(19) United States
(12) Patent Application Publication
(10) Pub. No.: US 2025/0271500 A1
(43) Pub. Date: Aug. 28, 2025

(54) ENTROPY BASED SOFTWARE CLOCK RECOVERY FOR REAL-EQUIVALENT-TIME OSCILLOSCOPES

(71) Applicant: Tektronix, Inc., Beaverton, OR (US)

(72) Inventor: Kan Tan, Portland, OR (US)

(21) Appl. No.: 19/049,821

(22) Filed: Feb. 10, 2025

Related U.S. Application Data
(60) Provisional application No. 63/556,827, filed on Feb. 22, 2024.

(51) Int. Cl. G01R 31/317; G01R 31/28

(52) U.S. Cl. CPC G01R 31/31706; G01R 31/2846; G01R 31/31725

(57) ABSTRACT

An oscilloscope having a Nyquist frequency lower than an analog bandwidth includes an input configured to receive a signal under test; an analog-to-digital converter (ADC) to receive the signal under test, sample the signal under test at a sample rate, and produce digital samples of the signal under test; one or more processors configured to execute code that causes the one or more processors to: determine a set of candidate unit intervals by generating corresponding candidate histograms using the candidate unit intervals; determine a best unit interval from the candidate unit intervals based upon entropy measures of each candidate histogram; and reconstruct a representation of the signal under test using the digital samples and the best unit interval.

### CROSS-REFERENCE TO RELATED APPLICATIONS

This disclosure is a non-provisional of and claims benefit from U.S. Provisional Application No. 63/556,827, titled “ENTROPY BASED SOFTWARE CLOCK RECOVERY FOR REAL-EQUIVALENT-TIME OSCILLOSCOPES,” filed on Feb. 22, 2024, the disclosure of which is incorporated herein by reference in its entirety.

### TECHNICAL FIELD

This disclosure relates to test and measurement instruments, and more particularly to clock recovery techniques for use in a test and measurement instrument.

### BACKGROUND

As stated in U.S. Pat. No. 11,789,051, filed Feb. 22, 2021, titled REAL-EQUIVALENT-TIME OSCILLOSCOPE, hereinafter “Tan,” the entire contents of which are hereby incorporated by reference into this application, the high-speed signaling progresses to higher speed for data center and other applications. For example, 26 Gb/s NRZ and 26 GBaud, 53 GBaud PAM4 signaling are used in 100/400 Gb Ethernet. See, e.g., “IEEE P802.3bs D3.5, Draft standard for ethernet amendment 10: media access control parameters, physical layers and management parameters for 200 Gb/s and 400 Gb/s operation,” 2017; “IEEE P802.3cd D3.5, Draft standard for ethernet amendment 3: media access control parameters for 50 Gb/s and physical layers and management parameters for 50 Gb/s, 100 Gb/s and 200 Gb/s operation,” 2018. 32 GBaud PAM4 signaling is used in PCIE Gen6. See, e.g., “PCI Express Base Specification 6.0, Version 0.7,” Specifications|PCI-SIG (pcisig.com) 2021.

For these applications, high-end real-time (RT) oscilloscopes and equivalent-time (ET) oscilloscopes are commonly used by R&D for debug and characterization. ET oscilloscopes are commonly used for volume production. Real-equivalent-time (RET) oscilloscopes provide a cost efficient and power efficient way to address the same measurement needs for the high-speed signaling.

In high-speed signaling scheme, there is a nominal value for unit interval (UI). The nominal UI is the inverse of nominal bitrate for NRZ or the Baud Rate for PAM4. For example, 32 GBaud is the nominal Baud Rate for PCIE Gen6. The actual Baud Rate, however, changes during data transmission. Part of the UI change is by design, for example, the SSC (spread spectrum clocking) scheme purposely down spreads the system clock by 5000 ppm, or, 0.5% of the nominal Baud Rate. Another part of the UI change is from the intrinsic system clock jitter as the system clock is not perfect. The clock data recovery unit is designed to track or reduce the impact of the low frequency jitter including SSC by making the recovered clock track the low frequency part of the system clock embedded in the data signal. Various software clock data recovery (SCDR) techniques have been developed for the real-time oscilloscopes where the raw sampled waveform is not aliased.

RET oscilloscopes have sample rate far below two times the Nyquist frequency required to perform real-time acquisition of the signal, resulting in aliasing in the raw sampled waveforms acquired on the RET oscilloscopes. Therefore, the regular SCDR methods designed for the real-time oscilloscopes cannot be used. Tan introduces a new SCDR for RET oscilloscope. However, the method in Tan has two challenges. One issue relates to the processing speed, and another involves handling signals with larger impairments.

### BRIEF DESCRIPTION OF THE DRAWINGS

FIG. 1 shows a plot of entropy versus probability for sending bit zero and bit one.

FIG. 2 shows a plot of entropy over an even probability distribution.

FIG. 3 shows a same distribution under modular operation with different offsets.

FIG. 4 shows an embodiment of a neural network for entropy based real-equivalent-time oscilloscopes.

FIG. 5 shows a block diagram of an embodiment of a real-equivalent-time oscilloscope with machine learning.

FIG. 6 shows two-dimensional histogram plots from various unit interval (UI) estimations.

FIG. 7 shows an output from a neural network for different signals with different UI estimation.

FIG. 8 shows an eye diagram on a RET scope samples after software clock recovery.

### DETAILED DESCRIPTION

Real-equivalent time (RET) oscilloscopes provide a lower-cost option to replace either real-time (RT) oscilloscopes or equivalent-time (ET) oscilloscopes for applicable applications. RT oscilloscopes can sample an input waveform in one pass. That is, the acquisition and the display can occur in the same time frame. To do this, conventional real-time oscilloscopes have a sampling rate high enough for an analog bandwidth to prevent aliasing when acquiring a signal under test with a high speed. Equivalent-time (ET) oscilloscopes use repetitions of patterns within a signal to reconstruct the waveform. A clock and data recovery (CDR) unit can cause a hardware trigger of the ET oscilloscope to take the samples. Because repetitive signals are being sampled, the bandwidth of an ET scope can far exceed its sample rate.

In contrast, as set out in Tan, real-equivalent time (RET) oscilloscopes have a sampling frequency below two times the Nyquist frequency required to perform real-time acquisition resulting in the acquired samples having aliasing. RET oscilloscopes determine the bit or baud rate of the signal by iteratively generating an eye diagram using windows of samples until the eye of the eye diagram has the widest opening. Eye diagrams comprise a two-dimensional (2D) histogram of the sampled waveform. The oscilloscope adjusts the bit or baud rate until that widest opening occurs. Once the oscilloscope had determined the bit and/or baud rate, the oscilloscope can place each sample in reconstructed signal. The reconstruction process does not require a hardware trigger to reconstruct the signal as the ET oscilloscope does.

As mentioned above, the above process has a lower processing speed than desired for high-speed signals, and the process does not handle signals with larger impairments well. Impairments could include such issues as jitter, as an example. In Tan, the process operates iteratively. For each eye diagram of a candidate unit interval, the process calculates the standard deviation of the jitter iteratively using different offsets. This process then repeats these iterations for each eye diagram. This process takes time, making the overall process slow.

The embodiments here instead use a measure of entropy of the waveform histogram for each of the eye diagrams associated with the candidate unit intervals. The process only measures the entropy once and selects the candidate unit interval with the lowest entropy. Lowest entropy means the highest concentration, which translates to the more accurate unit interval selection.

Entropy is a scientific concept and a measurable physical property most commonly associated with a state of disorder, randomness, or uncertainty. See https://en.wikipedia.org/wiki/Entropy for a discussion of entropy. Diverse fields have explored entropy from classical thermodynamics to statistical physics, and later to the information theory. The signals acquired by the oscilloscopes mostly relate to communication systems where the information theory is one of the fundamental theories.

Given a histogram, the Entropy value can be calculated in equation (1):

$$H = - {\sum }_{k = 1}^{n} p ( k ) log ( p ( k ) ) for p ( k ) > 0 k = 1 , 2 , … , n \qquad ( 1 )$$

where:
p(k) is the normalized number of hits on the k-th bin of a histogram representing probability:

$$p ( k ) = hits ( k ) / total hits$$

n is the number of bins.

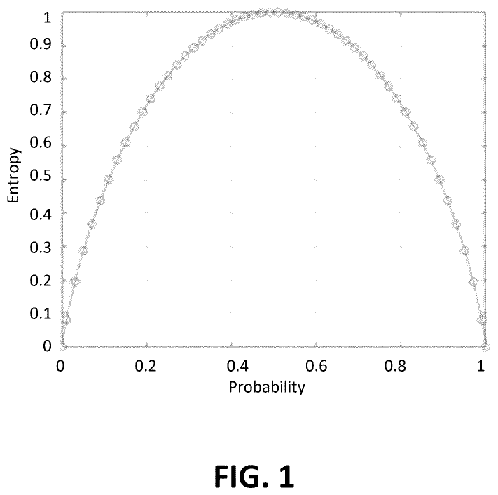

One example of entropy is regarding sending a bit with value of either 0 or 1. Assuming the possibility of sending bit 0 is p, then the possibility of sending bit 1 is 1-p. Based on the equation (1), the entropy can be calculated as a function of p, as shown in FIG. 1.

FIG. 1 indicates the entropy value reaches its minimum when only bit 0 or bit 1 is sent. The entropy value reaches its maximum when the chance of sending bit 0 and bit 1 is evenly distributed.

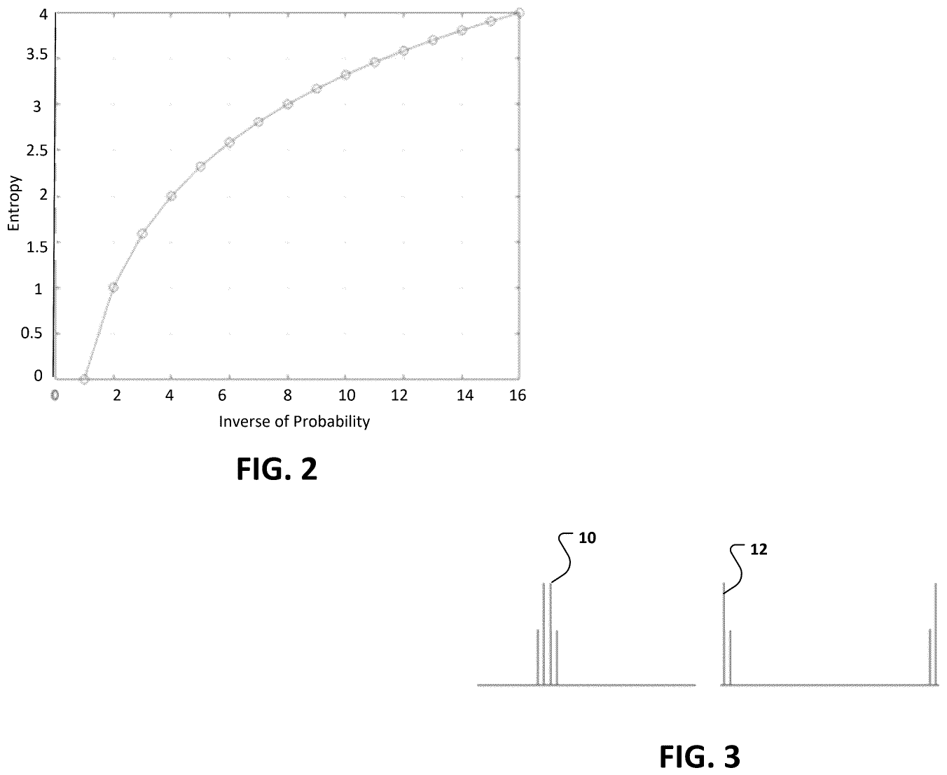

The other example is the entropy of even distribution. When the probability is evenly distributed to 2 possible values, the entropy value is 1, as shown in FIG. 1. When the probability is evenly distributed to n possible values, the corresponding entropy value is shown in FIG. 2

FIG. 2 indicates the entropy value increases when the possibility is evenly distributed to more possible values or bins. For example, the entropy value increases to 2 when the possibility is evenly distributed to 4 bins. The entropy value increases to 3 when distributed to 8 bins. In summary, less concentration yields higher entropy value.

The software clock data recovery for RET depends upon the observation that less accurate unit interval estimations cause more spread in the timing after the unit interval based modular operation. This means that less concentration exists in the samples, making the eye diagram less clear.

In one embodiment, one can use the entropy measure to determine which unit interval estimation has the most accuracy or is “the best” unit interval estimation. First, one computes a two-dimensional histogram from the RET samples for each candidate unit interval estimation of Tan. The process of Tan selects a set of unit interval estimations based upon the eye diagram for each candidate unit interval. One can calculate the entropy values of all the candidate unit intervals based upon the 2D histograms.

For a 2D histogram, the 2D entropy can be calculated as a single value using the same formula as equation (1), with the index covering all the grids in the 2D histogram. The 2-Dimensional entropy represents the randomness of the 2D histogram. The 2D entropy can be used for the RET software clock recovery.

Alternatively, one could select a vertical range in each 2D histogram and build a one-dimensional histogram at that vertical range. The vertical range could be selected around a point in the 2D histogram that corresponds to the average power, average voltage level, with 5% or other percentage of the signal amplitude as examples. One would then calculate the entropy from the 1-D histogram and select the unit interval corresponding to the 1D histogram having the lowest entropy value. As mentioned above, lower entropy means higher concentration, corresponds to the better unit interval estimation. An example may be helpful for ease of understanding, and without limitation. Consider a signal having the values between 0V and 1V. One may pick the average value, such as (0+1)/2=0.5V. One could then choose 5%, meaning [−2.5%+2.5%] around 0.5V. The amplitude is 0.5. The vertical range will be [0.5-2.5%*0.5, 0.5+2.5%*0.5]=[0.4875, 0.5125]. Alternatively, one could use 1D histograms as the candidate histograms to send to machine learning. In this embodiment, a vertical range is determined based upon the digital samples. The one or more processors would then select samples that lie within a selected vertical range and puts the timing of the selected samples into bins of a one-dimensional histogram by performing the modulus operation of the sampling timing with the estimated unit interval and use the operation results as the bin locations.

For comparison, the process disclosed in Tan uses the standard deviation to determine the best unit interval. The standard deviation needs to be calculated multiple times since standard deviation is sensitive to the offset of the 1D histogram. For example, because of the nature of the unit interval based modular operation of the 1D histogram set out above, the samples could be concentrated in the center (horizontally) of the eye diagram. However, because of the modular operation, with a time offset in the 1D histogram, the samples could be distributed at both ends (horizontally). The standard deviations differ between these two cases even though the unit interval estimations are the same. The only difference is the time offset, as shown in FIG. 3. To get the correct standard deviation value used to determine the accuracy of the unit interval estimation, multiple standard deviations are calculated with different time offsets to get the correct standard deviation value. The optimal time offsets yield the lowest standard deviation. This iterative process results in a slower calculation process.

In contrast, for the two distributions, 10 and 12, in FIG. 3, their entropy values are identical based on the equation (1). Since time offset does not affect the entropy measure, the calculation speed is improved over the standard deviation-based method. The entropy-based approach also performs better when the signals have more impairments such as jitter, noise, inter-symbol-interferences, as it emphasizes the randomness. The less accurate estimation of the unit interval results in more randomness in the 1D histogram compared to the more accurate estimation of the unit interval.

When the signals have significant impairments, the direct entropy-based software clock recovery cannot determine which unit interval estimation is better based on the 2D or 1D histogram approaches discussed above. In this case, machine learning could be helpful.

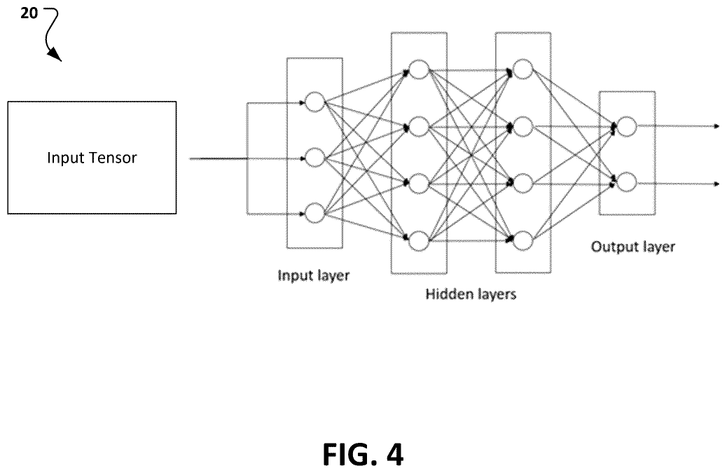

Machine learning using neural network provides a powerful tool. The neural network can look at the full 2D histogram instead of 1D histograms, as more information can be used efficiently. FIG. 4 shows an embodiment of a neural network structure. The neural network 20 receives the 2D histogram as its input. The label for the neural network for training is based on entropy. For different training cases, when the impairments increase, the entropy increases. When the unit interval estimation is less accurate, the entropy also increases. The entropy-based label can be interpolated and extrapolated based on the impairments and the unit interval estimation for training.

When the impairments are very large, the software clock recovery could fail even on real-time oscilloscopes. Machine learning has a unique advantage in this case. Because the training data is known, one can construct training data that has large impairments. The unit interval (UI) of the training data is known, and one can set the label accordingly. This gives the machine learning an advantage. After training, the machine learning can determine which UI estimation is good based on the model from training.

The impairments in the training data set have known values. For example, the jitter value, the noise value, and the ISI value for each training data are known. The label can be interpolated and extrapolated based upon these impairments. For example, the entropy value is H1 for training data 1 which has jitter value J1, noise value N1, ISI value I1. The entropy value is H2 for training data 2 with jitter value J2, noise value N2, ISI value I2. The entropy value H1 and H2 for training data 1 and training data 2 are good labels as they can be used to reliably determine the best UI estimation. If the entropy value for training data 3 can be not be used to reliably to determine the best UI estimation, then the label for training data 3 can be estimated by interpolation or extrapolation based on the labels from training data 1 and training data 2 and based on the impairments of training data 3 with jitter value J3, noise value N3, ISI value I3, and the impairments of training data 1 and training data 2.

After training, the neural network can determine which of the unit interval estimation is better. In the testing phase, the 2D histograms from various unit interval estimations are fed into the neural network. The neural network output indicates which one is the best estimation. The lower entropy measure of the selected unit interval means the better the unit interval estimation. Having the most accurate unit interval estimation ensures that the signal under test is evaluated correctly. Having inaccurate unit interval estimations could lead to the signal under test to be failed or passed incorrectly, when compared to the desired signal characteristics or test criteria for the signal.

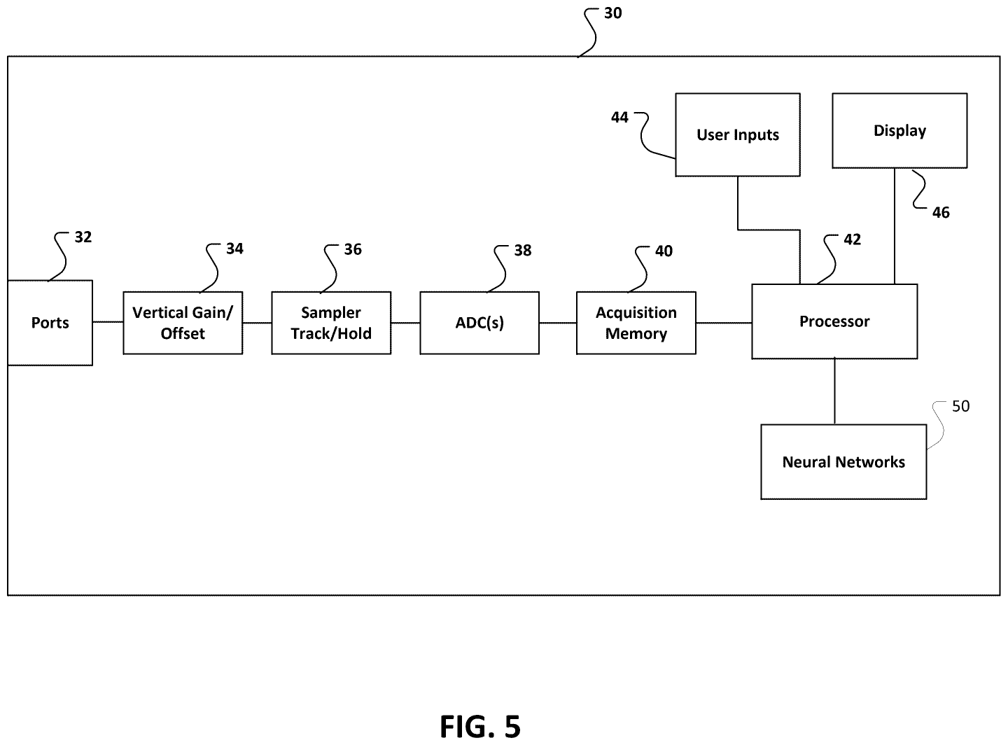

FIG. 5 shows an embodiment of an oscilloscope that can implement the above process based upon a signal under test received from a device under test (DUT). FIG. 5 illustrates an example block diagram of a real-equivalent-time test and measurement 30 instrument according to some configurations of the disclosure. The test and measurement instrument 30 includes one or more ports 32 which may be any electrical signaling medium. Ports 32 may include receivers, transmitters, and/or transceivers. Each port 32 is a channel of the test and measurement instrument 30.

The signals from the ports are then sent to a vertical gain/offset 34 which can adjust the offset or baseline of the received signal and scale the received signal. In some configurations or examples, the vertical gain/offset 34 may not include a vertical gain adjustment. If there is no vertical gain adjustment, vertical noise can be reduced, but there is also a decrease in the dynamic range. To address this, in some examples, an external attenuator and/or amplifier may be used to attenuate and/or amplify the incoming signal under test. The signal is sent to a sampler track and hold circuit 36 from the vertical gain/offset 34. The track and hold circuit 36 holds each signal steady for a period of time sufficient to enable digitization by a high-resolution analog-to-digital converter (ADC) 38.

The ADC 38 converts the analog signal from the track and hold circuit 36 to a digital signal. The ADC 38 has a sampling rate that is greater than equivalent-time test and measurement instruments, but less than real-time test and measurement instruments. For example, ADCs 38 can sample the signals from a few GS/s to tens of GS/s. In some configurations, the ADC 38 can sample the analog signal between 1 GS/s to 100 GS/s. In other configurations, the ADCs can sample the analog signal between 2 GS/s and 25 GS/s. The digitized signal from the ADCs 38 can then be stored in an acquisition memory 40.

One or more processors 42 may be configured to execute instructions from memory and may perform any methods and/or associated steps indicated by such instructions, such as receiving the acquired signals from the acquisition memory 40 and reconstructing the signal under test without the use of a hardware trigger or acquiring the sample in the high acquisition rate.

Memory 40 or any other memory on the test and measurement instrument 30 may be implemented as processor cache, random access memory (RAM), read only memory (ROM), solid state memory, hard disk drive(s), or any other memory type. Memory acts as a medium for storing data, computer program products, and other instructions.

User inputs 44 are coupled to the one or more processors 42. User inputs 44 may include a keyboard, mouse, trackball, touchscreen, and/or any other controls employable to allow a user to interact with a GUI on display 46. The display 46 may be a digital screen or any other monitor to display waveforms, measurements, and other data to a user. While the components of the test and measurement instrument 30 are depicted as being integrated within test and measurement instrument 30, it will be appreciated by a person of ordinary skill in the art that any of these components can be external to the test and measurement instrument 30 and can be coupled to the test and measurement instrument 30 in any conventional manner. For example, in some examples, the one or more neural networks 50 may be remote from the test and measurement instrument 30.

In one embodiment, the oscilloscope uses the neural network to 50 to determine the best unit interval for the clock recovery. The neural network may reside on-board the oscilloscope and may be implemented as software executed by the same one or more processors that operate the oscilloscope. Alternatively, they may reside in a separate component within the oscilloscope or may reside in an external computing device attached to the oscilloscope. Regardless, the one or more processors execute the code to operate or interface with the neural network.

The implementation of machine learning, including the neural networks 50, an embodiment of which is shown in FIG. 4, can improve both the speed and accuracy of the selection of the best, meaning the most accurate, unit interval. The clock recovery process used in RET scopes employing the embodiments here overcome the previous issues.

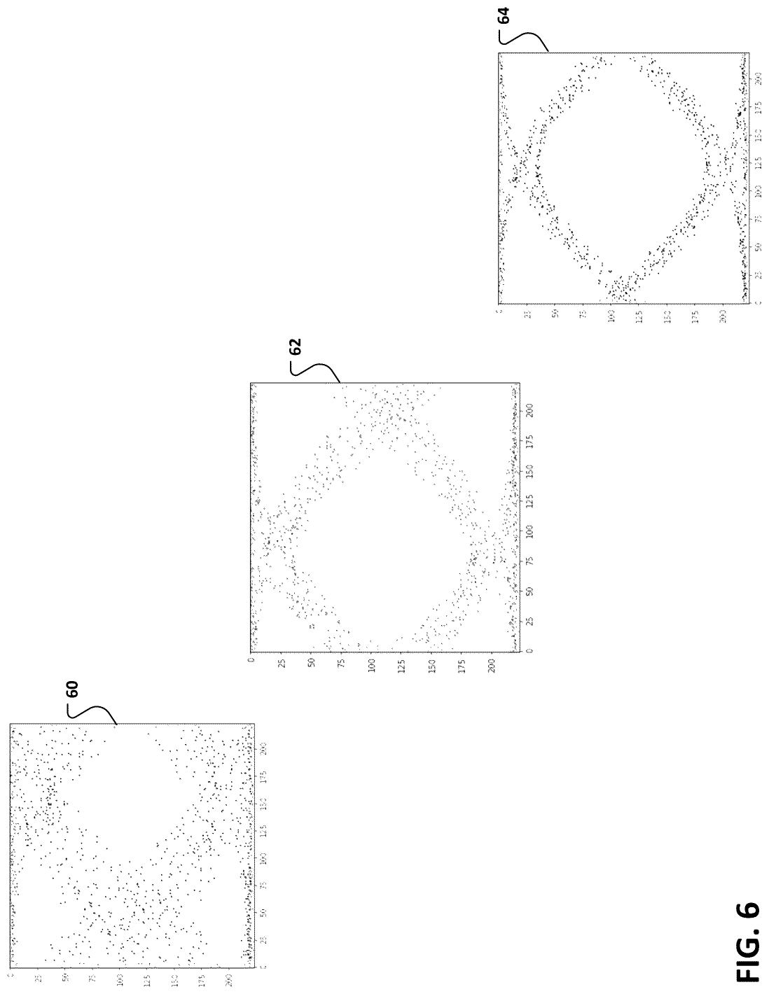

FIG. 6 shows three different histogram plots for different unit intervals. The top plot 60 has the least accurate unit interval estimation, and bottom plot 64 has the best, with plot 62 lying somewhere in between. Each unit interval has a time offset. The time offsets shown in the histogram plots do not impact entropy value. Certain neural networks such as Convolutional Neural Network (CNN) is not impacted by the rotation of the 2D histograms.

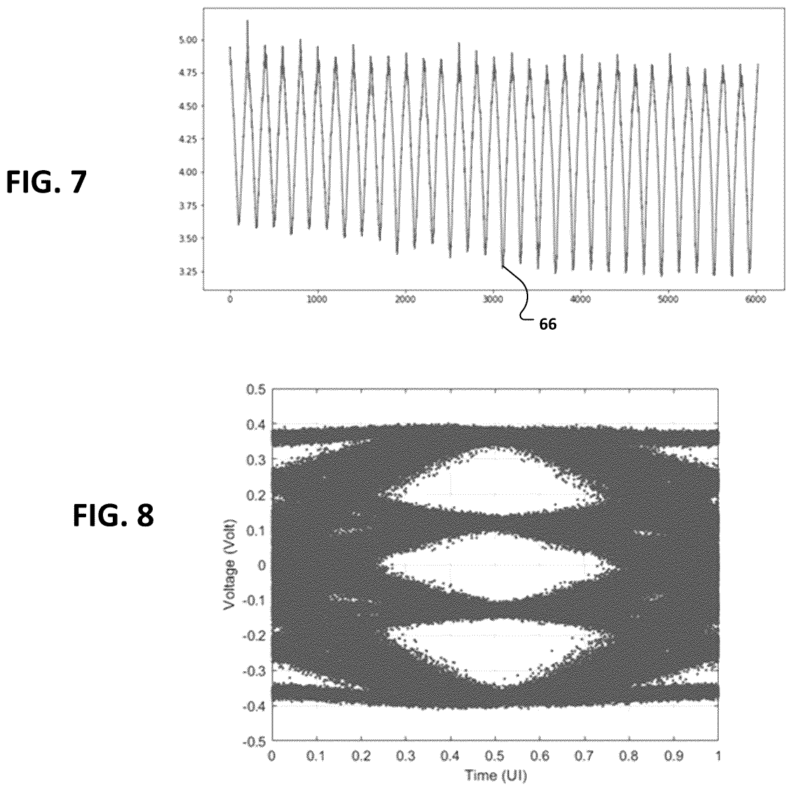

FIG. 7 shows a result of testing cases using a trained CNN model based ResNet34 neural network structure, for the RET software clock recovery. Along the horizontal axis for this particular embodiment, every 201 of the points represent one signal with 201 estimations of unit interval. The center point 66 among the 201 points has the best unit interval estimation when the testing cases are created. FIG. 7 shows that the neural network outputs the lowest value for the 2D histogram corresponding to the best unit interval estimation. Different signals have different entropy levels, shown in every 201 points in FIG. 7. Each “V” shape constitutes one signal.

Once the unit interval is estimated correctly, the rest of software clock recovery can be processed the same way as described in Tan. Using the sample rate and the frequency, the process can recover the clock. Using the recovered clock, the process generates an original waveform by reassigning timing for the samples of the waveform to make the samples located at the right timing position of the pattern. The pattern waveform can then be interpolated and resampled to have even timing spacing. The evenly spaced pattern waveform eliminates aliasing.

FIG. 8 shows an eye diagram on a RET scope after the samples have undergone clock recovery and resampling. As can be seen, the eye diagrams have clear openings.

In this manner, one can receive the benefits of an RET oscilloscope that does not suffer from processing delays or lower accuracy unit intervals.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is an oscilloscope having a Nyquist frequency lower than an analog bandwidth, comprising: an input configured to receive a signal under test; an analog-to-digital converter (ADC) to receive the signal under test, sample the signal under test at a sample rate, and produce digital samples of the signal under test; one or more processors configured to execute code that causes the one or more processors to: determine a set of candidate unit intervals by generating corresponding candidate histograms using the candidate unit intervals; determine a best unit interval from the candidate unit intervals based upon entropy measures of each candidate histogram; and reconstruct a representation of the signal under test using the digital samples and the best unit interval.

Example 2 is the oscilloscope of Example 1, wherein the one or more processors are further configured to execute code that causes the one or more processors to determine if the representation of the signal under test meets test criteria.

Example 3 is the oscilloscope of either of Examples 1 or 2, further comprising one or more neural networks, and the code that causes the one or more processors to determine the best unit interval comprises code that causes the one or more processors to: send the candidate histograms to the one or more neural networks; and receive an identification from the one or more neural networks of the best candidate unit interval.

Example 4 is the oscilloscope of Example 3, wherein the one or more processors are further configured to execute code to train the one or more neural networks.

Example 5 is the oscilloscope of Example 4, wherein one or more processors are configured to execute code that causes the one or more processors to train the one or more neural networks by creating one or more training data sets comprised of histograms and an associated entropy value for each histogram.

Example 6 is the oscilloscope of Example 4, wherein the one or more processors are further configured to generate training sets for histograms from signals with impairments too high to allow the histograms to be used in data sets by interpolation using neighboring training sets.

Example 7 is the oscilloscope of any of Examples 1-6, wherein the code that causes the one or more processors to determine the best unit interval comprises code to cause the one or more processors to: generate two-dimensional histograms as the candidate histograms; and calculate an entropy value for each of the two-dimensional histograms and select as the best unit interval the unit interval corresponding to the two-dimensional histogram having the lowest entropy value.

Example 8 is the oscilloscope of any of Examples 1-7, wherein the code that causes the one or more processors to determine the best unit interval comprises code to cause the one or more processors to: calculate two-dimensional histograms as the candidate histograms; calculate a one-dimensional histogram for each of the two-dimensional histograms within a vertical range in the two-dimensional histogram; calculate an entropy value for each of the one-dimensional histograms; and select as the best unit interval the unit interval corresponding to the one-dimensional histogram having the lowest entropy value.

Example 9 is the oscilloscope of Example 8, wherein the code that causes the one or more processors to calculate the one-dimensional histogram within the vertical range causes the one or more processors to select the vertical range including a point in the two-dimensional histogram corresponding to one of average signal power and average voltage level, plus and minus a percentage of the signal amplitude.

Example 10 is the oscilloscope of any of Examples 1-9, wherein the code that causes the one or more processors to determine the best unit interval comprises code to cause the one or more processors to: determine a vertical range based upon the digital samples; select samples that lie within a selected vertical range; and perform modular operations on the timing of the selected samples and then put results into bins of a one-dimensional histogram based upon the best unit interval.

Example 11 a method of reconstructing a signal under test using an oscilloscope having a Nyquist frequency lower than an analog bandwidth, comprising: receiving a signal under test; sampling the signal under test to produce digital samples of the signal under test; determining a set of candidate unit intervals for the digital samples by generating corresponding candidate histograms using the candidate unit intervals; determining a best unit interval from the candidate unit intervals based upon entropy measures of each candidate histogram; and reconstructing a representation of the signal under test using the digital samples and the best unit interval.

Example 12 is the method of Example 11, further comprising determining if the representation of the signal under test meets test criteria.

Example 13 is the method of either of Examples 11 or 12, wherein determining the best unit interval comprises: sending candidate two dimensional histograms to one or more neural networks; and receiving an identification from the one or more neural networks of the best candidate unit interval.

Example 14 is the method of Example 13, further comprising training the one or more neural networks.

Example 15 is the method of Example 14, wherein training the one or more neural networks comprises creating one or more training data sets comprised of two-dimensional histograms and an associated entropy value for each two-dimensional histogram.

Example 16 is the method of Example 14, further comprising generating training sets for histograms from signals with impairments too high to allow the histograms to be used in data sets by estimating the training set using neighboring training sets.

Example 17 is the method of any of Examples 11-16, wherein determining the best unit interval comprises calculating an entropy value for each of the two-dimensional histograms and selecting as the best unit interval the unit interval corresponding to the two-dimensional histogram having the lowest entropy value.

Example 18 is the method of any of Examples 11-17, wherein determining the best unit interval comprises: calculating a one-dimensional histogram for each of the two-dimensional histograms using a vertical range in the two-dimensional histogram; calculating an entropy value for each of the one-dimensional histograms; and selecting as the best unit interval the unit interval corresponding to the one-dimensional histogram having the lowest entropy value.

Example 19 is the method of Example 18, wherein calculating the one-dimensional histogram using the vertical range comprises selecting the vertical range at a point in the two-dimensional histogram corresponding to one of average signal power and average voltage level, plus and minus a percentage of the signal amplitude.

Example 20 is the method of any of Examples 11-20, wherein determining the best unit interval comprises: determining a vertical range based upon the digital samples; selecting samples that lie within a selected vertical range; and performing modular operations on the timing of the selected samples and then put results into bins of a one-dimensional histogram based upon the best unit interval.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. An oscilloscope having a Nyquist frequency lower than an analog bandwidth, comprising:
an input configured to receive a signal under test;
an analog-to-digital converter (ADC) to receive the signal under test, sample the signal under test at a sample rate, and produce digital samples of the signal under test;
one or more processors configured to execute code that causes the one or more processors to:
determine a set of candidate unit intervals by generating corresponding candidate histograms using the candidate unit intervals;
determine a best unit interval from the candidate unit intervals based upon entropy measures of each candidate histogram; and
reconstruct a representation of the signal under test using the digital samples and the best unit interval.

2. The oscilloscope as claimed in claim 1, wherein the one or more processors are further configured to execute code that causes the one or more processors to determine if the representation of the signal under test meets test criteria.

3. The oscilloscope as claimed in claim 1, further comprising one or more neural networks, and the code that causes the one or more processors to determine the best unit interval comprises code that causes the one or more processors to:
send the candidate histograms to the one or more neural networks; and
receive an identification from the one or more neural networks of the best candidate unit interval.

4. The oscilloscope as claimed in claim 3, wherein the one or more processors are further configured to execute code to train the one or more neural networks.

5. The oscilloscope as claimed in claim 4, wherein one or more processors are configured to execute code that causes the one or more processors to train the one or more neural networks by creating one or more training data sets comprised of histograms and an associated entropy value for each histogram.

6. The oscilloscope as claimed in claim 4, wherein the one or more processors are further configured to generate training sets for histograms from signals with impairments too high to allow the histograms to be used in data sets by interpolation using neighboring training sets.

7. The oscilloscope as claimed in claim 1, wherein the code that causes the one or more processors to determine the best unit interval comprises code to cause the one or more processors to:
generate two-dimensional histograms as the candidate histograms; and
calculate an entropy value for each of the two-dimensional histograms and select as the best unit interval the unit interval corresponding to the two-dimensional histogram having the lowest entropy value.

8. The oscilloscope as claimed in claim 1, wherein the code that causes the one or more processors to determine the best unit interval comprises code to cause the one or more processors to:
calculate two-dimensional histograms as the candidate histograms;
calculate a one-dimensional histogram for each of the two-dimensional histograms within a vertical range in the two-dimensional histogram;
calculate an entropy value for each of the one-dimensional histograms; and
select as the best unit interval the unit interval corresponding to the one-dimensional histogram having the lowest entropy value.

9. The oscilloscope as claimed in claim 8, wherein the code that causes the one or more processors to calculate the one-dimensional histogram within the vertical range causes the one or more processors to select the vertical range including a point in the two-dimensional histogram corresponding to one of average signal power and average voltage level, plus and minus a percentage of the signal amplitude.

10. The oscilloscope as claimed in claim 1, wherein the code that causes the one or more processors to determine the best unit interval comprises code to cause the one or more processors to:
determine a vertical range based upon the digital samples;
select samples that lie within a selected vertical range; and
perform modular operations on the timing of the selected samples and then put results into bins of a one-dimensional histogram based upon the best unit interval.

11. A method of reconstructing a signal under test using an oscilloscope having a Nyquist frequency lower than an analog bandwidth, comprising:
receiving a signal under test;
sampling the signal under test to produce digital samples of the signal under test;
determining a set of candidate unit intervals for the digital samples by generating corresponding candidate histograms using the candidate unit intervals;
determining a best unit interval from the candidate unit intervals based upon entropy measures of each candidate histogram; and
reconstructing a representation of the signal under test using the digital samples and the best unit interval.

12. The method as claimed in claim 11, further comprising determining if the representation of the signal under test meets test criteria.

13. The method as claimed in claim 11, wherein determining the best unit interval comprises:
sending candidate two dimensional histograms to one or more neural networks; and
receiving an identification from the one or more neural networks of the best candidate unit interval.

14. The method as claimed in claim 13, further comprising training the one or more neural networks.

15. The method as claimed in claim 14, wherein training the one or more neural networks comprises creating one or more training data sets comprised of two-dimensional histograms and an associated entropy value for each two-dimensional histogram.

16. The method as claimed in claim 14, further comprising generating training sets for histograms from signals with impairments too high to allow the histograms to be used in data sets by estimating the training set using neighboring training sets.

17. The method as claimed in claim 11, wherein determining the best unit interval comprises calculating an entropy value for each of the two-dimensional histograms and selecting as the best unit interval the unit interval corresponding to the two-dimensional histogram having the lowest entropy value.

18. The method as claimed in claim 11, wherein determining the best unit interval comprises:
calculating a one-dimensional histogram for each of the two-dimensional histograms using a vertical range in the two-dimensional histogram;
calculating an entropy value for each of the one-dimensional histograms; and
selecting as the best unit interval the unit interval corresponding to the one-dimensional histogram having the lowest entropy value.

19. The method as claimed in claim 18, wherein calculating the one-dimensional histogram using the vertical range comprises selecting the vertical range at a point in the two-dimensional histogram corresponding to one of average signal power and average voltage level, plus and minus a percentage of the signal amplitude.

20. The method as claimed in claim 11, wherein determining the best unit interval comprises:
determining a vertical range based upon the digital samples;
selecting samples that lie within a selected vertical range; and
performing modular operations on the timing of the selected samples and then put results into bins of a one-dimensional histogram based upon the best unit interval.
